(19) United States
(12) Patent Application Publication
(10) Pub. No.: US 2007/0205430 A1
(43) Pub. Date: Sep. 6, 2007

(54) METHOD AND STRUCTURE OF REFRACTORY METAL REACH THROUGH IN BIPOLAR TRANSISTOR

(76) Inventors: David S. Collins, Williston, VT (US); Louis D. Lanzerotti, Burlington, VT (US); Edward J. Nowark, Essex Junction, VT (US); Steven H. Voldman, South Burlington, VT (US)

Correspondence Address: GREENBLUM & BERNSTEIN, P.L.C., 1950 ROLAND CLARK DRIVE, RESTON, VA, 20191, US

(21) Appl. No.: 11/276,510

(22) Filed: Mar. 3, 2006

(51) Int. Cl. H01L 31/111

(52) U.S. Cl. 257/117

(57) ABSTRACT

Structure and method of structure in which a contact, e.g., low resistance; ohmic; resulting in Schottky isolation, is coupled to a doped region that is buried in a substrate. In a bipolar transistor having a collector region formed below an upper surface of a substrate, a trench is formed through a portion of the collector region, and the sidewall(s) and/or bottom of the trench are doped, e.g., by ion implantation or dopant. The trench is filled with a conductor, e.g., a refractory metal such as tungsten.

### FIELD OF THE INVENTION

The present invention relates to a reach through (sinker) structure with doping for contacts to produce a low resistance connection and a process for forming the same. The fabricated structure can be for bipolar transistors (NPN, PNP) or other device structures with sub-collectors or triple well isolation. The present invention also relates to a schottky bordered collector heterojunction bipolar transistor and process for forming the same.

### BACKGROUND DESCRIPTION

A bipolar junction transistor is typically composed of two back-to-back p-n junctions that share a thin common region. Contacts are made in all three regions, the two outer regions, i.e., the emitter and collector, and the middle region, i.e., the base. The device is referred to as bipolar since operation involves both types of mobile carriers, i.e., electrons and holes.

Heterojunction bipolar transistors (HBTs) are bipolar transistors composed of at least two different semiconductors, such that energy bandgap and all other material properties can be different in the emitter, base, and collector. The use of heterojunctions provides a degree of design freedom that results in vastly improved devices as compared to its homojunction counterpart.

Collector resistance or additional capacitance impacts silicon germanium heterojunction bipolar transistors (SiGe HBT) and npn (or pnp) transistor performance. Prior art has employed reach through implants which induce local scattering of dopants, are space consuming, and require additional implants/mask levels. With reach through implants, contact landing is located at the silicon surface.

With low doped subcollectors or n-well regions, the doping concentration is not high enough to provide a good ohmic contact for the subcollector or well region. As a result, an additional dopant source must be used on at least one surface of the refractory metal contact region.

Further, because conventional HBTs are partially isolated from one another by a trench surrounding the device and by high doping implant regions around the trench, well to substrate capacitance and device-to-device leakage current can negatively affect device performance.

In one conventional system, a device isolation region surrounds first and second device regions of a semiconductor substrate and a patterned deep-trench isolation region is embedded through the device isolation region into the substrate. First and second bipolar transistors are respectively formed in the device regions, and each transistor has a collector region and a base region in the substrate, and an emitter embedded in an insulation layer above the base region. Space savings, low collector resistance and low collector-substrate capacitance are achieved by embedding a collector trench contact into boundary portions of the deep-trench and device isolation regions deeper into the substrate to establish an electrical contact with the collector region. The insulation layer can be etched to create openings for the collector trenches simultaneously with openings for the emitters and base regions in a single photoetching process.

### SUMMARY OF THE INVENTION

In one aspect, the present invention is directed to a device that includes a contact arranged in a trench extending below the silicon surface into a subcollector, and a buried doped region formed along at least one of a bottom of the trench, which is formed, at least in part, in the subcollector, and at least one surface of the trench.

In one aspect, the present invention is directed to a method for an integrated circuit device. The method includes forming a trench extending from a top silicon surface into a subcollector, forming a contact in the trench, and forming a buried doped region formed along at least one of a bottom of the trench, which is formed at least in part in the subcollector, and at least one surface of the trench.

In one aspect, the present invention is directed to an integrated circuit that includes a trench isolation (TI) structure with an added metal collector contact extending from the top silicon surface into a subcollector, a doped region along at least one of: at least one surface of the trench and a bottom of the trench, and a refractory metal contained within the trench, without dependence on deep trench (DT) isolation.

### BRIEF DESCRIPTION OF THE DRAWINGS

FIGS. 1-19 schematically illustrate a process according to a first embodiment of the invention for forming the structure of the instant invention;

FIG. 20 schematically illustrates a final arrangement according to a second embodiment of the invention;

FIG. 21 schematically illustrates a final arrangement according to a third embodiment of the invention;

FIG. 22 schematically illustrates a final arrangement in accordance with a fourth embodiment of the invention; and

FIG. 23 schematically illustrates a final arrangement in accordance with a fifth embodiment of the invention.

### DETAILED DESCRIPTION OF EMBODIMENTS OF THE INVENTION

The present invention is directed to a refractory reach through metal structure using a trench isolation (TI) process with an added metal collector contact. According to the invention, a dopant source is used to implant ions to at least one surface or a bottom of the trench, and the refractory metal reach through is integrated with either trench isolation (TI) or Schottky-diode isolation in a heterojunction bipolar transistor (HBT). The present invention has utility in CMOS dual well, CMOS triple well, BiCMOS SiGe HBT passives and derivatives, complimentary BiCMOS and BiCMOS triple well structures.

A bipolar transistor, e.g., a homojunction/heterojunction bipolar transistor can be formed by implantation or epitaxial growth to include a base, emitter and collector. Further, the bipolar transistor can include a subcollector and deep trench (DT) or trench isolation (TI). Other devices can also include a subcollector or deep trench (DT) or trench isolation (TI). Such other devices may include, e.g., Schottky-diodes, varactors, P-N well diodes, passive and active elements suitable for triple well metal oxide semiconductor field effect transistor (MOSFET) structures, and electrostatic discharge protection diodes or guardrings. Within the context of the instant application, deep trench (DT), trench isolation (TI), and shallow trench isolation (STI) are discrete terms. In this regard, STI is used in generally all devices, and DT is formed below the STI and is filled with isolation material. As discussed below, the present invention more closely resembles trench isolation (TI).

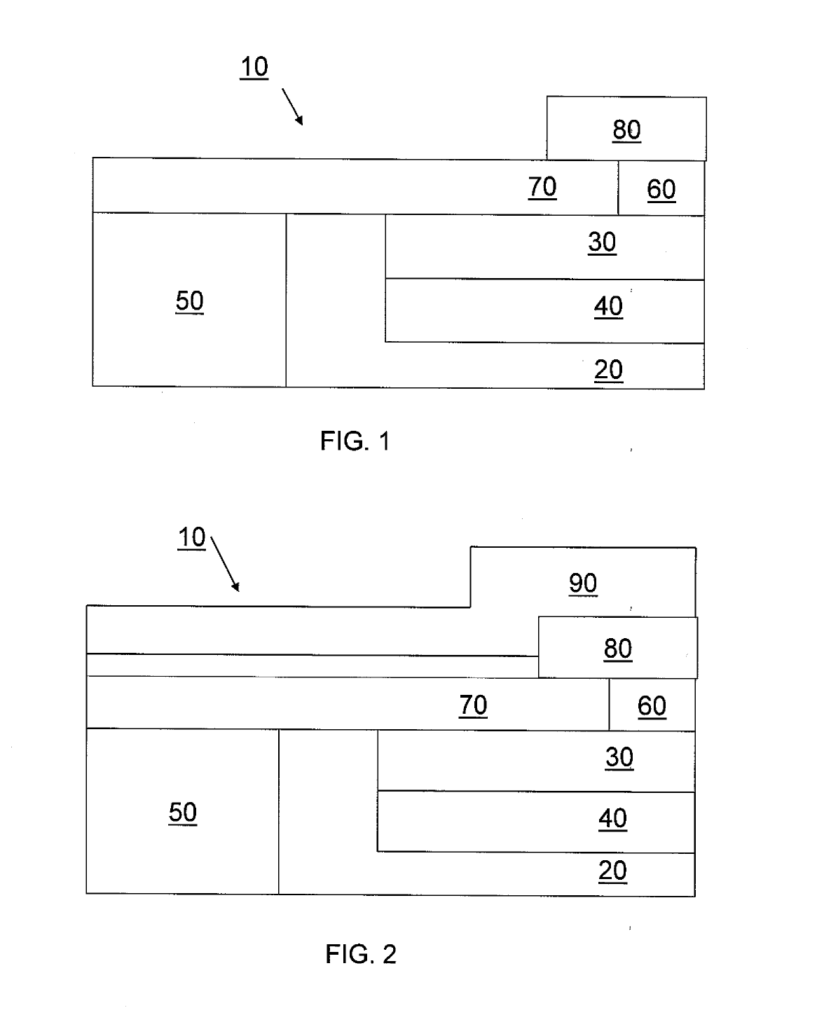

A first embodiment, illustrated in FIGS. 1-19, provides a reach through (sinker) structure with refractory metal liner and contact region. A dopant source is used to out-diffuse dopants on a trench isolation (TI) trough surface to provide a good ohmic contact. As shown in FIG. 1, a defined front end of line (FEOL) process of a SiGe HBT 10 (or SiGeC HBT (silicon germanium carbon HBT)) is shown prior to typical trench isolation (TI) or contact (CA) formation. HBT 10 includes a silicon substrate 20, which can be formed from any semiconductor, including GaAs or InGaAs, into which a collector 30 and subcollector 40 are arranged in a layered configuration. Collector 30 and subcollector 40 are doped with different levels of dopant, e.g., an N-type dopant such as arsenic, phosphorus, and/or antimony, by implantation or epitaxial growth. Subcollector 40 will generally have a greater concentration of dopant with reference to collector 30. Both collector 30 and subcollector 40 may have a layer thickness between 1-5 μm, and preferably between 3.5-4 μm. Adjacent substrate 20 has substantially the doping concentration of the starting substrate (wafer) or has substantially the doping concentration of the starting wafer epitaxial film growth. A further P-region is formed on collector 30 by P-type doping, such as boron. Shallow trench isolation (STI) 70 is formed from the upper surface of substrate 20 to extend downwardly to collector 30 and P-well 50, and adjacent P-region 60. In this regard, a shallow trench isolation (STI) has a depth less than 0.5 μm, which should be distinguished from trench isolation (TI), which has a depth of 0.5-5 μm, and from deep trench (DT) isolation, which has a depth of 5-12 μm. In this embodiment, STI 70 can be formed of insulator oxide such as SiO₂ dielectric. STI 70 and P-region 60 can have a layer thickness less than 0.5 μm. A base and emitter 80, composed, e.g., of an NPN device such as a SiGe transistor, is arranged to straddle the junction of P-region 60 and STI 70.

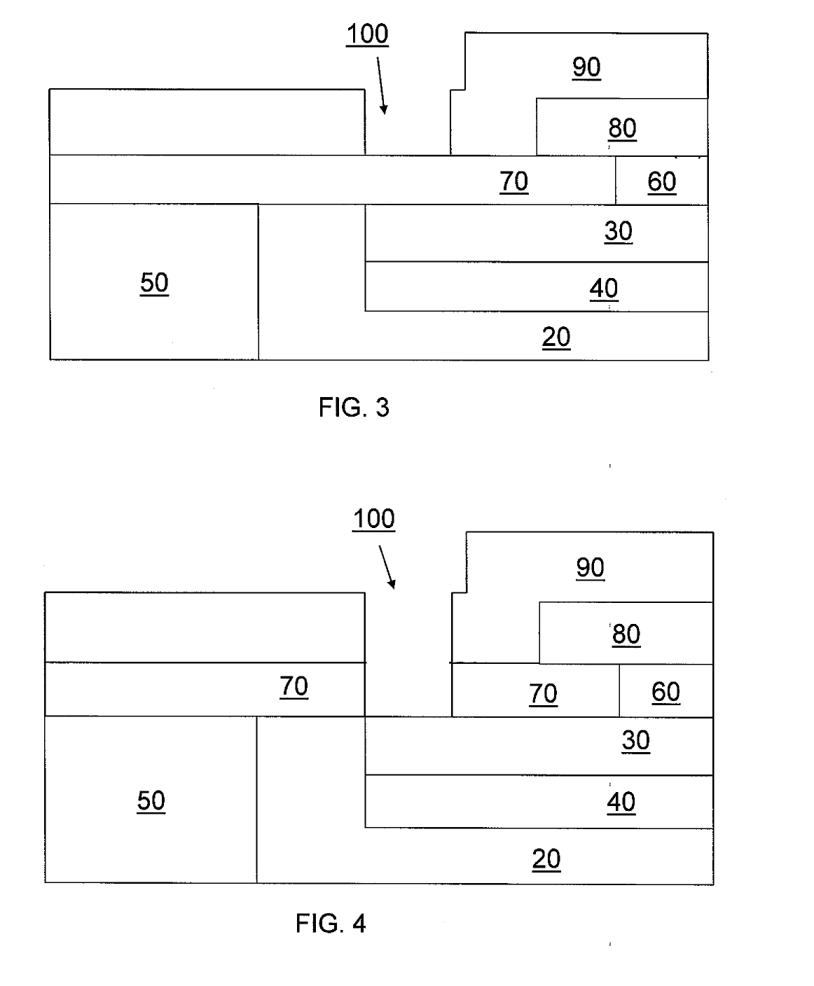

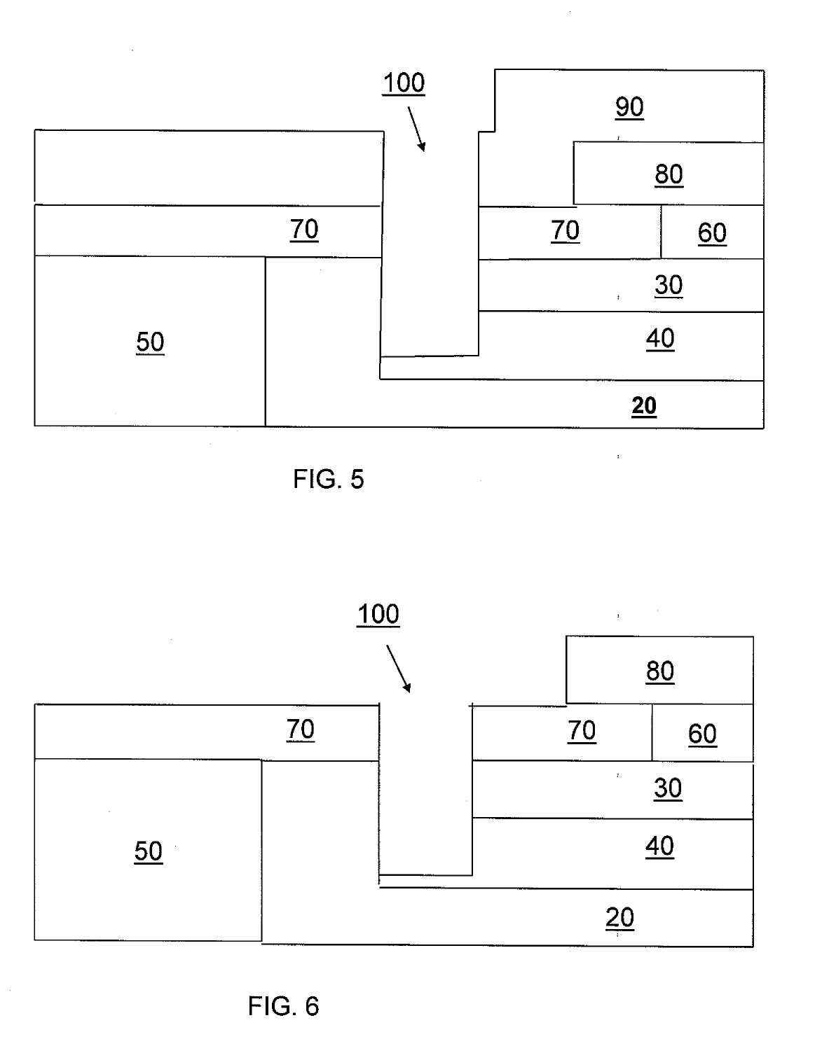

As illustrated in FIG. 2, a trench isolation (TI) resist layer 90 is deposited over the top of the device structure, thereby covering at least base and emitter 80 and STI 70. TI resist layer 90 may be formed from a standard photoresist material and have a thickness of about 2.5 μm. In FIG. 3, TI resist layer 90 is patterned to remove a portion of its material down to STI 70, which is where the trench isolation (TI) trough 100 will be formed. FIG. 4 shows the result of an oxide etch, which removes a portion of STI 70 that corresponds to the patterned portion of TI resist layer 90. A silicon etch is performed to remove portions of the collector and subcollector that correspond to the patterned portions of TI resist layer 90 and of STI 70, as shown in FIG. 5. In this embodiment, the trench isolation (TI) trough 100 should extend 0.5 to 5 μm, but should not extend all the way to substrate 20, because sufficient subcollector material should remain to ensure good electrical connection. In contrast, the collector and subcollector are partially removed, e.g., by silicon etch, as close as possible to the vertical edge of substrate 20, with preferably no collector or subcollector material on the exterior perimeter surface of the trench isolation (TI) trough. However, in this embodiment, TI resist layer 90 is also patterned so as not to remove substrate 20 material along the outer perimeter wall of the trench isolation trough 100. TI resist layer 90 is stripped off the device structure, i.e., at least from STI 70 and base and emitter 80, by any suitable and conventional strip/removal procedure, as shown in FIG. 6.

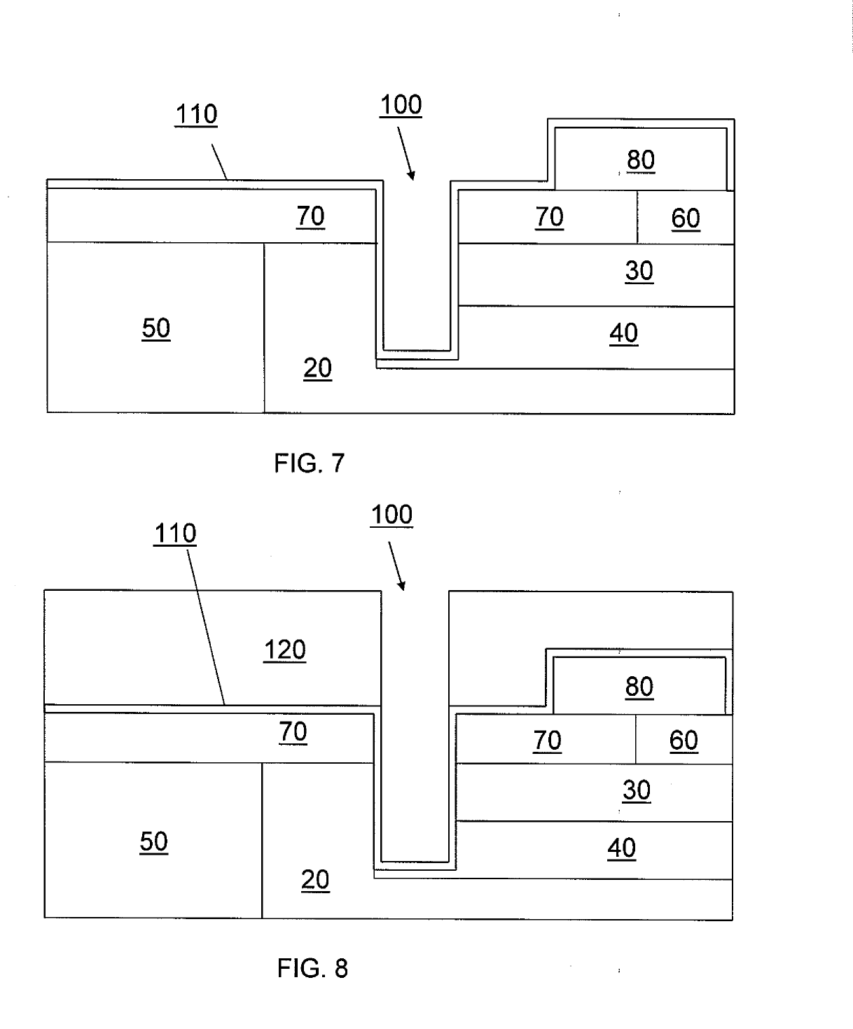

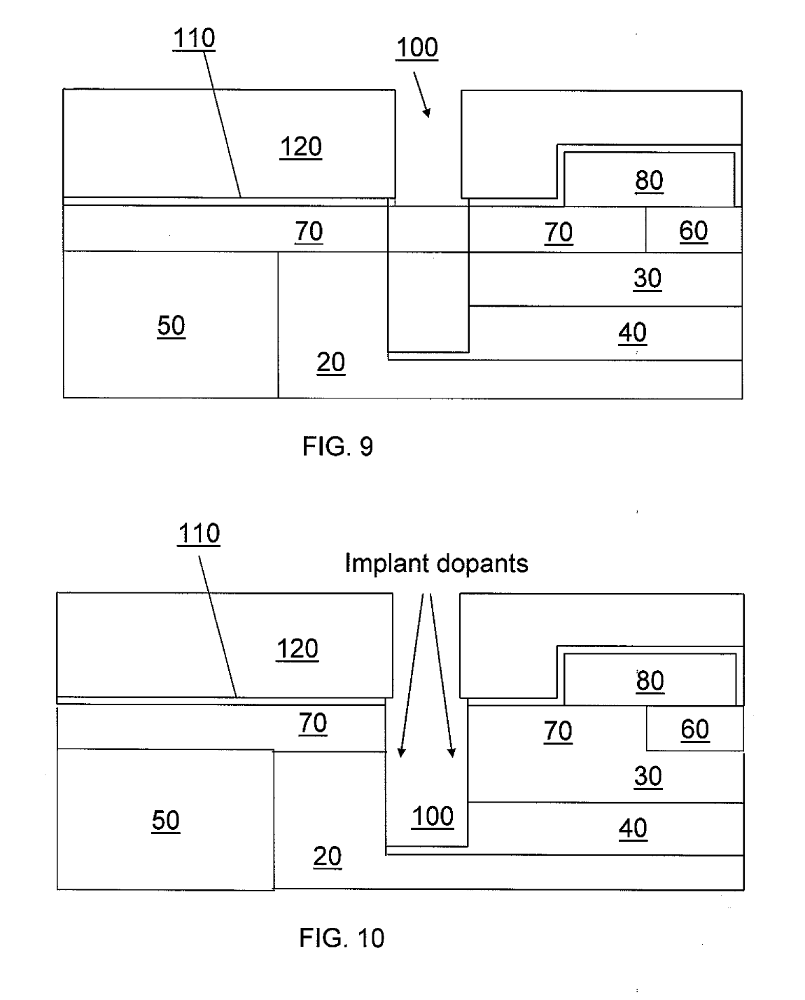

In FIG. 7, contact formation mask level occurs through CA passivation, in which a conductive liner 110, e.g., a refractory metal film such as Ta, TaN, Ti, TiN, W, etc., having a thickness greater than 0.01 μm is applied over the device structure and within trench isolation (TI) trough 100. Liner 110 can be tantalum/tantalum nitride, or titanium/titanium nitride. In FIG. 8, a trench contact removal mask (i.e., a resist and pattern) is applied over liner 110 on the device structure. However, it is noted that, while mask 120 covers the vertical extent of the liner 110 formed on the sidewalls of trench isolation (TI) trough 100, liner 110 covering the bottom of trench isolation (TI) trough 100 is not covered by mask 120. A trench contact etch is performed in FIG. 9, in which liner 110 along the sidewalls and bottom of the trench isolation (TI) trough 100 is removed.

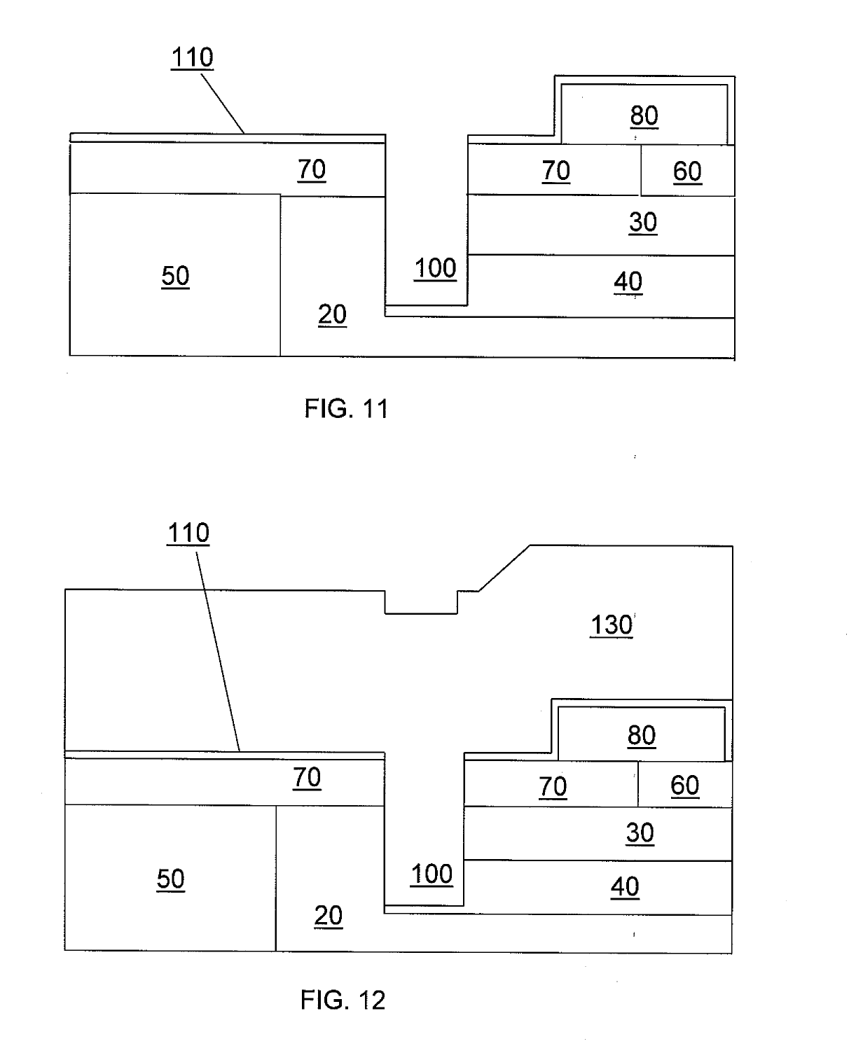

FIG. 10 shows the adding or implanting of dopants, e.g., any n-type dopant, into trench isolation (TI) trough 100. This implantation in conjunction with a rapid thermal anneal process out-diffuses dopants on the sidewall/bottom. In this way, dopant concentration is increased to provide ohmic contact on interior walls of trench 100. However, trench contact resist 120 is removed, as shown in FIG. 11, prior to the rapid thermal anneal for the implantation, such that and the device is then cleaned. Thus, liner 110 is atop the device structure, but no liner 110 is provided along the now doped sidewalls/bottom of trench isolation (TI) trough 100. Adding or implantation in conjunction with a rapid thermal anneal process out-diffusing dopants on the sidewall/bottom of the trench isolation (TI) trough can alternatively be applied prior to CA liner deposition.

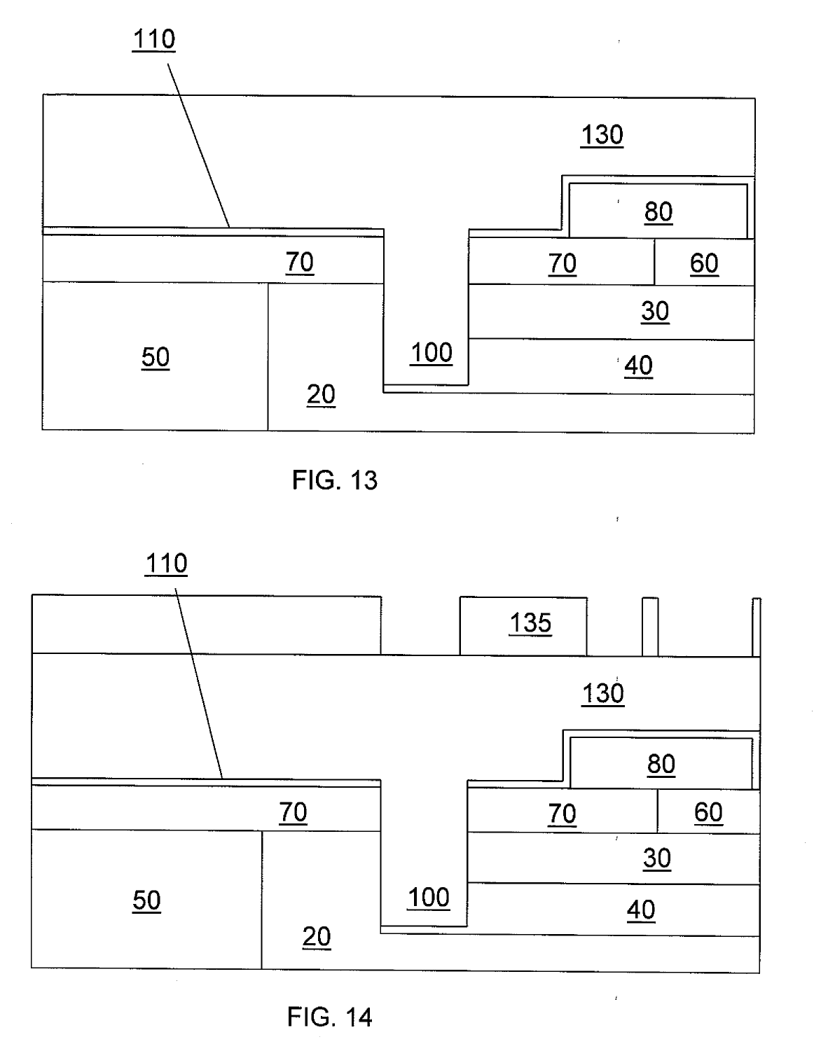

In a next part of the process, illustrated in FIG. 12, an insulator 130, e.g., borophosphorosilicate glass (BPSG) or phosphorosilicate glass, is applied over the device structure and within trench isolation (TI) trough 100, and, in FIG. 13, the insulator 130 is polished to a planar surface. The thickness of insulator 130 over silicon substrate (20) top surface, and base and emitter 80 is greater than 0.1 μm.

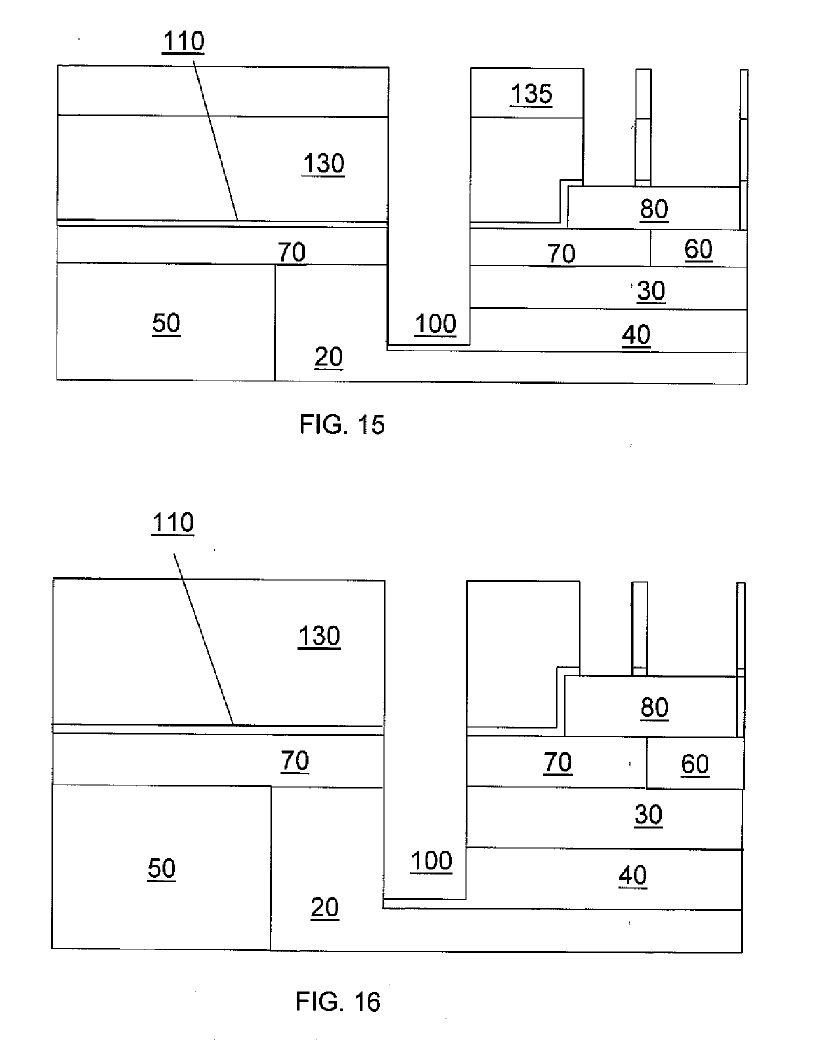

In FIG. 14, a contact CA photo resist and pattern 135 are formed on the planar surface of insulator 130. In this regard, it is noted that the pattern is open over trench isolation (TI) 100, as well as in two places over base and emitter 80. An insulator etch is performed in FIG. 15, in which liner 110 is removed to the base and emitter 80, and then photo resist is removed in an appropriate and conventional manner, e.g., stripping or etching, and the surface is cleaned in FIG. 16.

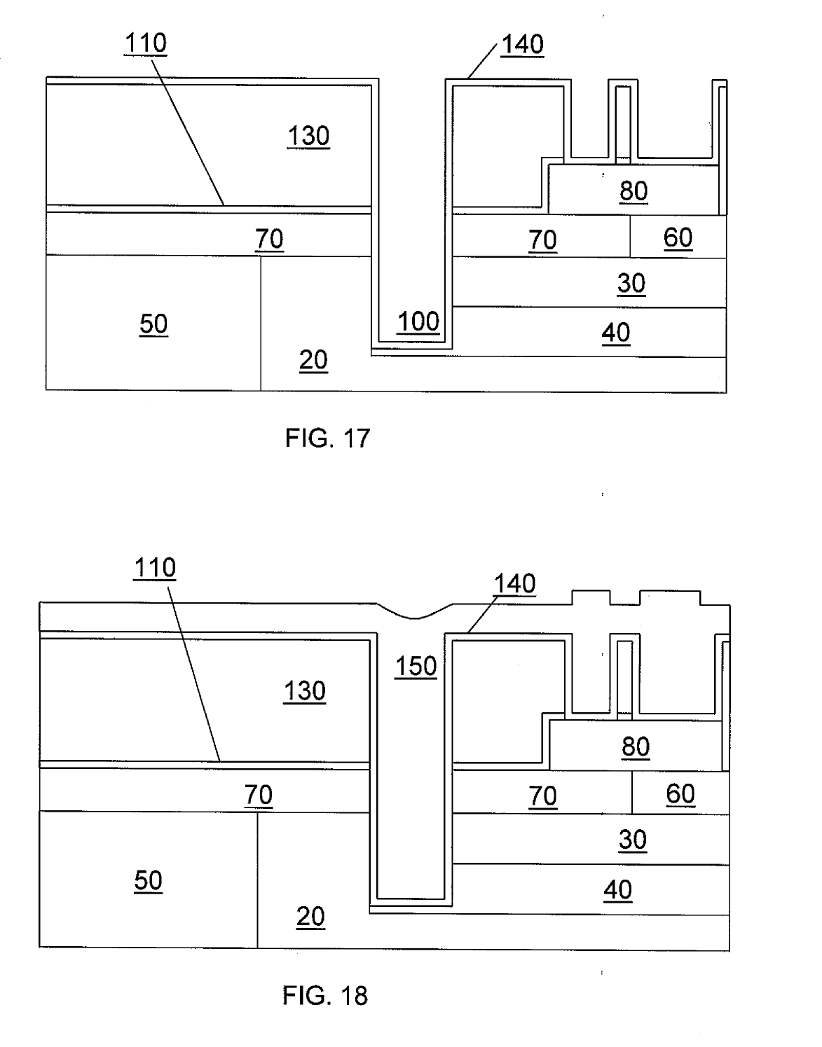

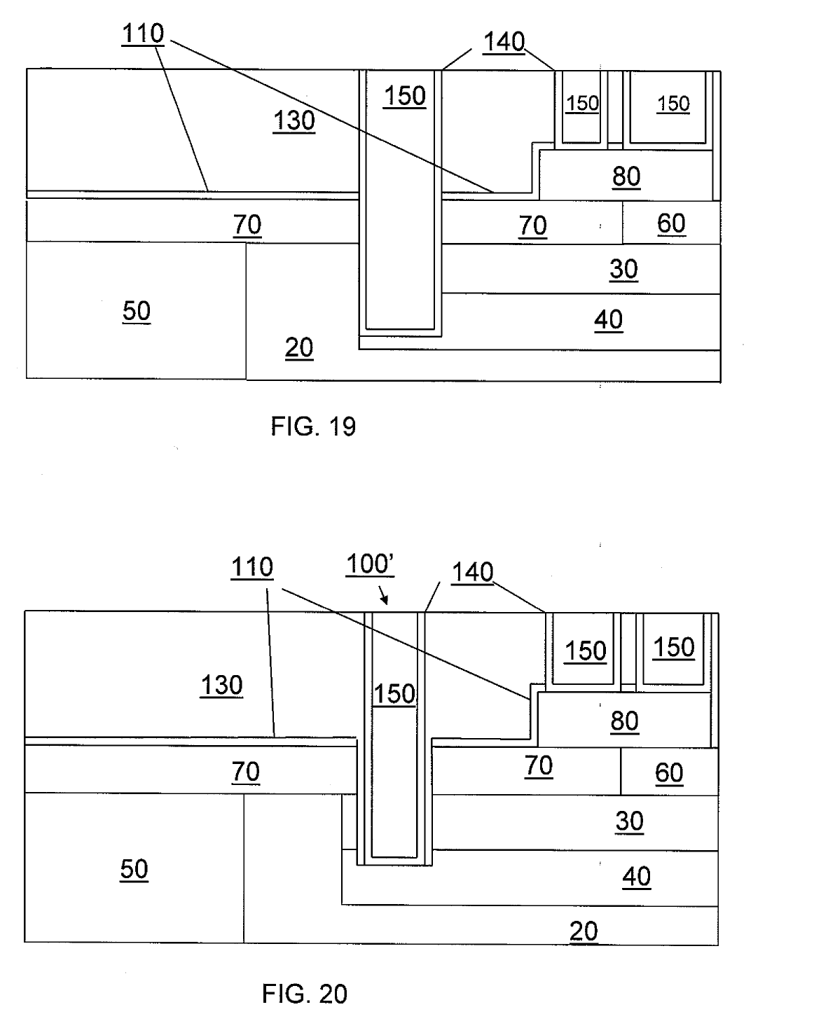

A conductive layer 140 is applied over the device structure to cover the vertical, as well as horizontal surfaces, in FIG. 17, so that conductive layer 140 is in contact with portions of base and emitter 80 and with bottom and sides of trench isolation (TI) trough 100. In FIG. 18, a refractory metal 150, e.g., tungsten, is applied over the device structure by CA deposition. The upper surface of the device is smoothed, e.g., by CA polishing, to remove the refractory metal 150 and conductor 140 arranged vertically above insulator 130, as shown in FIG. 19. At this point, typical back end of line (BEOL) processing can be performed, e.g., metal formation.

In a second embodiment, the final arrangement of which is illustrated in FIG. 20, the reach through structure has an insulator sidewall and a refractory metal film and insulator free bottom for electrical connection to the subcollector and refractory metal filled contact region. The doped sidewall can be placed on the surface that is non-insulating. The second embodiment essentially follows the process discussed above in FIGS. 1-19, except where noted. The start of the process of the second embodiment, like the first embodiment, begins with the defined front end of line (FEOL) process of a SiGe HBT 10 (or SiGeC HBT) is shown prior to typical trench isolation (TI) or contact (CA) formation. HBT 10 includes a silicon substrate 20, which can be formed from any semiconductor, including GaAs or InGaAs, into which a collector 30 and subcollector 40 are arranged in a layered configuration. Collector 30 and subcollector 40 are doped with different levels of dopant, e.g., an N-type dopant such as arsenic, phosphorus, and/or antimony, by implantation or epitaxial growth. Subcollector 40 will generally have a greater concentration of dopant with reference to collector 30. Both collector 30 and subcollector 40 may have a layer thickness between 1-5 μm, and preferably between 3.5-4 μm. Adjacent substrate 20 has substantially the doping concentration of the starting substrate (wafer) or has substantially the doping concentration of the starting wafer epitaxial film growth. A further P-region is formed on collector 30 by P-type doping, such as boron. Also, atop collector 30, and upper surface of substrate 20, and P-well 50, and adjacent P-region 60, is a shallow trench isolation (STI) 70 formed of insulator oxide such as SiO₂ dielectric. STI 70 and P-region 60 can have a layer thickness less than 0.5 μm. A base and emitter 80, composed, e.g., of an NPN device such as a SiGe transistor, is arranged to straddle the junction of P-region 60 and STI 70.

A trench isolation (TI) resist layer is deposited over the top of the device structure, thereby covering at least base and emitter 80 and STI 70. TI resist layer may be formed from a standard photoresist material and have a thickness of about 2.5 μm. The next part of the process differs from the first embodiment, where TI resist layer is patterned to remove a portion of its material down to STI 70, which is where a trench isolation (TI) trough 100′ will be formed. However, in contrast to the first embodiment, the pattern is formed so that the trench isolation (TI) trough to be formed will be within the collector 30 and subcollector 40. As a result of the oxide etch, a portion of STI 70 that corresponds to the patterned portion of TI resist layer is removed. Then, a silicon etch is performed to remove portions of the collector and subcollector that correspond to the patterned portions of TI resist layer and of STI 70. Likewise in this embodiment, trench isolation (TI) trough 100′ does not extend all the way to substrate 20, because sufficient subcollector material should remain to ensure good electrical connection. Moreover, as noted above, portions of collector 30 and subcollector 40 are arranged between trench isolation (TI) trough 100′ and substrate 20. Next, TI resist layer is stripped off the device structure, i.e., at least from STI 70 and base and emitter 80, by any suitable and conventional strip/removal procedure.

Contact formation mask level occurs through CA passivation, in which a conductive liner 110, having a thickness greater than 0.01 μm is applied over the device structure and within trench isolation (TI) trough 100′. Liner 110 can be tantalum/tantalum nitride, or titanium/titanium nitride or other refractive metal. A trench contact removal mask (i.e., a resist and pattern) is then applied over liner 110 on the device structure. However, it is noted that, while the mask covers the vertical extent of the liner 110 formed on the sidewalls of trench isolation (TI) trough 100′, liner 110 covering the bottom of trench isolation (TI) trough 100′ is not covered by the mask. A trench contact etch is performed, in which liner 110 along the sidewalls and bottom of trench isolation (TI) trough 100′ is removed.

Adding or implanting of dopants, e.g., any N-type dopant, into trench isolation (TI) trough 100′ occurs, and this implantation, in conjunction with a rapid thermal anneal process, out-diffuses dopants on the sidewall/bottom. Trench contact resist is removed, prior to the rapid thermal anneal, and the device is cleaned, such that liner 110 is atop the device structure, but no liner 110 is provided along the now doped sidewalls/bottom of trench isolation (TI) trough 100′. Adding or implantation in conjunction with a rapid thermal anneal process out-diffusing dopants on the sidewall/bottom of the trench isolation (TI) trough can alternatively be applied prior to CA liner deposition.

In a next part of the process, an insulator 130, e.g., borophosphorosilicate glass (BPSG) or phosphorosilicate glass, is applied over the device structure and within trench isolation (TI) trough 100′, and the insulator 130 is then polished to a planar surface. The thickness of insulator 130 over the silicon substrate (20) top surface, and base and emitter 80 is greater than 0.1 μm.

A contact CA photo resist and pattern are formed on the planar surface of insulator 130. In this regard, it is noted that the pattern, while not as wide as trench isolation (TI) trough 100′, is open over trench isolation (TI) 100′, as well as in two places over base and emitter 80. An insulator etch is performed such that a layer of insulation remains along the sidewalls of trench isolation 100′. The photo resist is removed in an appropriate and conventional manner, e.g., stripping or etching, and the surface is cleaned. Moreover, it is noted that the liner 110 is removed to the base and emitter 80.

A conductive layer 140 is applied over the device structure to cover the vertical, as well as horizontal surfaces so that conductive layer 140 is in contact with portions of base and emitter 80 and with bottom and insulated sides of trench isolation (TI) 100′. A refractory metal 150, e.g., tungsten, is applied over the device structure by CA deposition. The upper surface of the device is smoothed, e.g., by CA polishing, to remove the refractory metal 150 and conductor 140 arranged vertically above insulator 130. At this point, typical back end of line (BEOL) processing can be performed, e.g., metal formation.

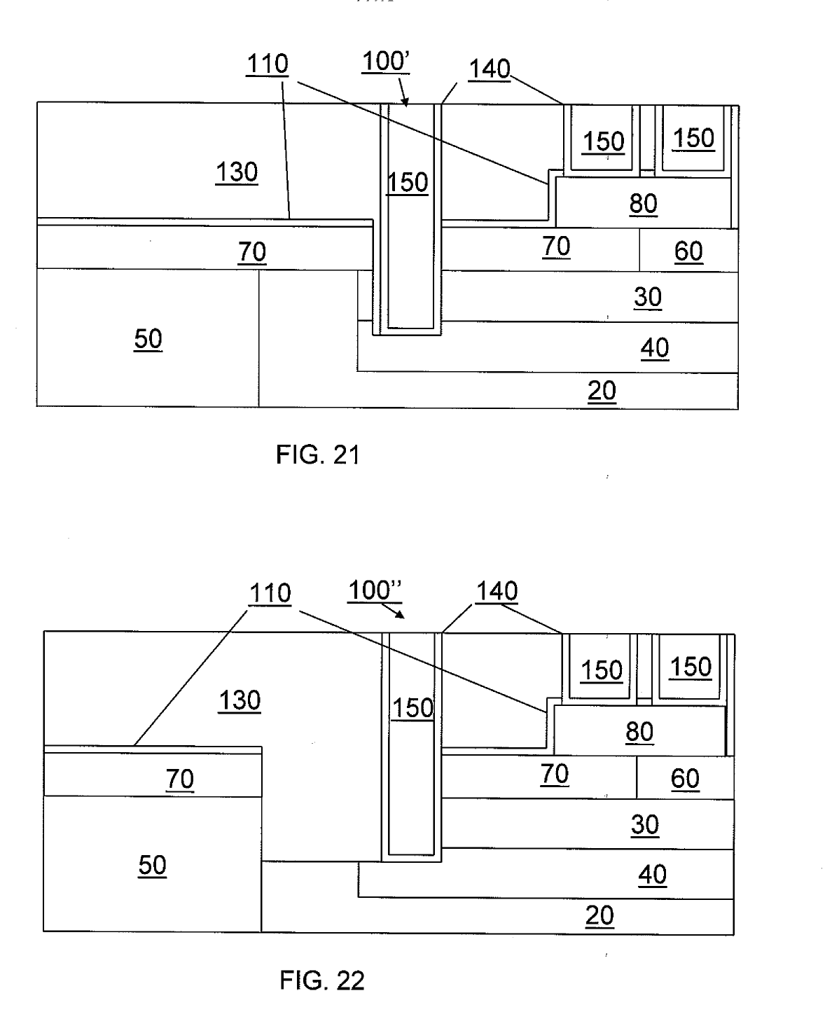

In a third embodiment, the final arrangement of which is illustrated in FIG. 21, the reach through structure has an insulator sidewall, i.e., an outside wall, and a refractory metal liner and a tungsten filled contact region for edge isolation and electrical contact. Ohmic contact can be formed using a dopant source or implantation. This process for fabricating this third embodiment is similar to that of the second process, except where noted. The third embodiment process is the same as the second embodiment from the beginning of the process to the polishing of insulator 130 to a planar surface, in which the thickness of insulator 130 over silicon substrate (20) top surface, and base and emitter 80 is greater than 0.1 μm.

A contact CA photo resist and pattern are formed on the planar surface of insulator 130. In this regard, it is noted that the pattern, like that in the first embodiment, has a same width as and is open over trench isolation (TI) 100′, as well as in two places over base and emitter 80. An insulator etch is performed so that a layer of insulation remains along one of the sidewalls of trench isolation (TI) 100′, e.g., the sidewall adjacent the vertical junction of substrate 20 and collector 30/subcollector 40. Moreover, it is noted that the liner 110 is removed to the base and emitter 80. The photo resist is removed in an appropriate and conventional manner, e.g., stripping or etching, and the surface is cleaned.

A conductive layer 140 is applied over the device structure to cover the vertical, as well as horizontal surfaces so that conductive layer 140 is in contact with portions of base and emitter 80 and with bottom and insulated sides of trench isolation (TI) trough 100′. A refractory metal 150, e.g., tungsten, is applied over the device structure by CA deposition. The upper surface of the device is smoothed, e.g., by CA polishing, to remove the refractory metal 150 and conductor 140 arranged vertically above insulator 130. At this point, typical back end of line (BEOL) processing can be performed, e.g., metal formation.

In a fourth embodiment, the final arrangement of which is illustrated in FIG. 22, the reach through structure is arranged to abut TI isolation on the device sidewall. The doped contact sidewall is completed using implantation or dopant source. This fourth embodiment is the same as the previous embodiments with regard to FIGS. 1 and 2, when resist layer 90 is deposited onto the surface of HBT 10.

Thereafter, in a next part of the process, a TI resist layer is patterned to remove a portion of its material down to STI 70, which is where a trench isolation (TI) trough 100″ will be formed. However, in contrast to trenches 100 and 100′, the pattern is formed so that trench isolation (TI) 100″ will be formed through the vertical junction of substrate 20 and collector 30/subcollector 40, and substrate 20 will be removed to the vertical junction with the P-well. An oxide etch then removes a portion of STI 70 that corresponds to the patterned portion of TI resist layer 90. A silicon etch is performed to remove portions of substrate 20, collector 30 and subcollector 40 that correspond to the patterned portions of TI resist layer and of STI 70. Likewise in this embodiment, trench isolation (TI) 100″ does not extend all the way through subcollector 40 to its horizontal junction with substrate 20, because sufficient subcollector material should remain to ensure good electrical connection. TI resist layer is then stripped off the device structure, i.e., at least from STI 70 and base and emitter 80, by any suitable and conventional strip/removal procedure.

Contact formation mask level occurs through CA passivation, in which a conductive liner 110, having a thickness greater than 0.01 μm is applied over the device structure and within trench isolation trough 100″. Liner 110 can be tantalum/tantalum nitride, or titanium/titanium nitride or other refractive metal. A trench contact removal mask (i.e., a resist and pattern) is applied over liner 110 on the device structure. However, it is noted that, while the mask covers the vertical extent of the liner 110 formed on the sidewalls of trench isolation (TI) trough 100″, liner 110 covering the bottom of trench isolation (TI) trough 100″ is not covered by the mask. A trench contact etch is performed, in which liner 110 along the sidewalls and bottom of trench isolation trough 100″ is removed.

Next, the adding or implanting of dopants, e.g., any N-type dopant, into trench isolation (TI) trough 100″ occurs. This implantation, in conjunction with a rapid thermal anneal process, out-diffuses dopants on the sidewall/bottom. Trench contact resist is removed, prior to the rapid thermal anneal, and the device is cleaned, such that liner 110 is atop the device structure, but no liner 110 is provided along the now doped sidewalls/bottom of trench isolation (TI) trough 100″. Adding or implantation in conjunction with a rapid thermal anneal process out-diffusing dopants on the sidewall/bottom of the trench isolation (TI) trough can alternatively be applied prior to CA liner deposition.

In a next part of the process, an insulator 130, e.g., borophosphorosilicate glass (BPSG) or phosphorosilicate glass, is applied over the device structure and within trench isolation (TI) trough 100″, and the insulator 130 is then polished to a planar surface. The thickness of insulator 130 over silicon substrate (20) top surface, and base and emitter 80 is greater than 0.1 μm.

A contact CA photo resist and pattern are formed on the planar surface of insulator 130, in which the pattern, while not as wide as trench isolation (TI) 100″, is open over trench isolation (TI) 100″, as well as in two places over base and emitter 80. Moreover, the patterned opening over trench isolation (TI) trough 100″ is not as wide as the portion of trench 100″ in collector 30/subcollector 40. An insulator etch is performed such that a layer of insulation remains along one of the sidewalls of trench isolation (TI) 100″, while the other side is etched along the vertical junction at collector 30/subcollector 40. Moreover, it is noted that the liner 110 is removed to the base and emitter 80. The photo resist is removed in an appropriate and conventional manner, e.g., stripping or etching, and the surface is cleaned.

A conductive layer 140 is applied over the device structure to cover the vertical, as well as horizontal surfaces, so that conductive layer 140 is in contact with portions of base and emitter 80 and with bottom and insulated sides of trench isolation (TI) trough 100″. A refractory metal 150, e.g., tungsten, is applied over the device structure by CA deposition. The upper surface of the device is smoothed, e.g., by CA polishing, to remove the refractory metal 150 and conductor 140 arranged vertically above insulator 130. At this point, typical back end of line (BEOL) processing can be performed, e.g., metal formation.

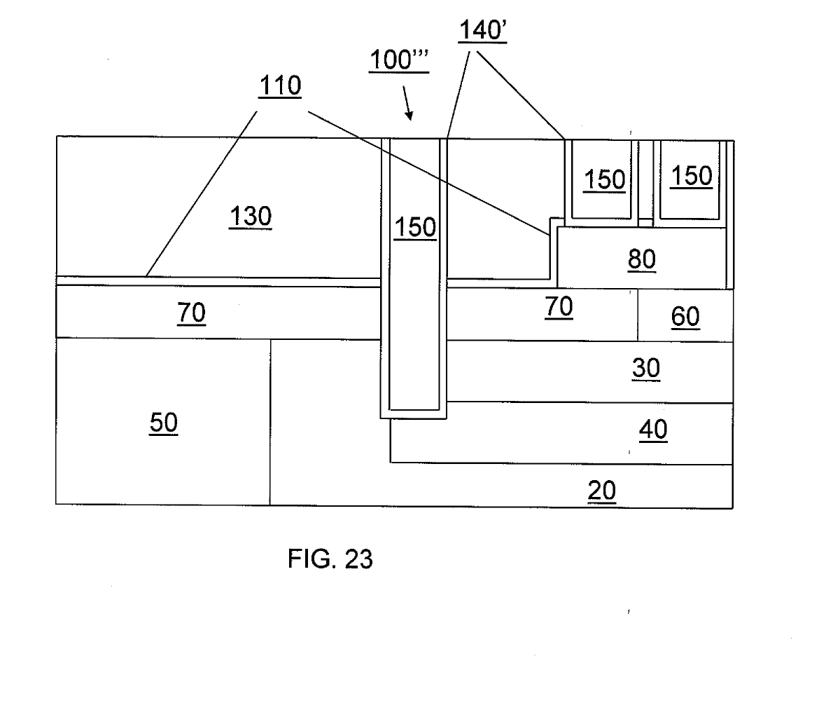

In a fifth embodiment, the final arrangement being illustrated in FIG. 23, the invention is directed to a method and structure of Schottky-bordered collector silicon germanium heterojunction bipolar transistor (SiGe HBT) or silicon germanium carbon heterojunction bipolar transistor (SiGeC HBT). This fifth embodiment is the same as the previous embodiments with regard to FIGS. 1 and 2, when the resist layer is deposited onto the surface of HBT 10.

The next part of the process, a TI resist layer is patterned to remove a portion of its material down to STI 70, which is where a trench isolation (TI) trough 100″′ will be formed through the vertical junction of substrate 20 and collector 30/subcollector 40. However, in contrast to trench isolation (TI) 100″, the pattern is formed so that trench isolation (TI) trough 100″′ will only remove a portion of substrate 20, so that the vertical junction between substrate 20 and P-well 50 remains. Preferably, more of substrate 20 will remain than will be removed in the etching (discussed below). An oxide etch, which removes a portion of STI 70 that corresponds to the patterned portion of TI resist layer. A silicon etch is performed to remove portions of substrate 20, collector 30 and subcollector 40 that correspond to the patterned portions of TI resist layer and of STI 70. Likewise in this embodiment, trench isolation (TI) trough should 100″′ does not extend all the way through subcollector 40 to its horizontal junction with substrate 20, because sufficient subcollector material should remain to ensure good electrical connection. TI resist layer is stripped off the device structure, i.e., at least from STI 70 and base and emitter 80, by any suitable and conventional strip/removal procedure.

Contact formation mask level occurs through CA passivation, in which a conductive liner 110, having a thickness greater than 0.01 μm is applied over the device structure and within trench isolation (TI) trough 100″′, Liner 110 can be tantalum/tantalum nitride, or titanium/titanium nitride or other refractive metal. A trench contact removal mask (i.e., a resist and pattern) is applied over liner 110 on the device structure. However, it is noted that, while the mask is formed to cover the vertical extent of the liner 110 formed on the sidewalls of trench isolation (TI) trench 100″′, liner 110 covering the bottom of trench isolation (TI) trough 100″′ is not covered by the mask. A trench contact etch is performed, in which liner 110 along the sidewalls and bottom of trench isolation (TI) trough 100″ is removed.

Next, the adding or implanting of vertically oriented dopants, e.g., any N-type dopant, into the bottom of trench isolation (TI) trough 100″′ occurs. This implantation in conjunction with a rapid thermal anneal process out-diffuses dopants on the bottom. Trench contact resist is removed, prior to the rapid thermal anneal, and the device is cleaned, such that liner 110 is atop the device structure, but no liner 110 is provided along the now doped bottom of trench isolation (TI) trough 100″′. Adding or implantation in conjunction with a rapid thermal anneal process out-diffusing dopants on the bottom of the trench isolation (TI) trough can alternatively be applied prior to CA liner deposition.

In a next part of the process, an insulator 130, e.g., borophosphorosilicate glass (BPSG) or phosphorosilicate glass, is applied over the device structure and within trench isolation (TI) trough 100″′, and the insulator 130 is polished to a planar surface. The thickness of insulator 130 over the silicon substrate (20) top surface, and base and emitter 80 is greater than 0.1 μm.

A contact CA photo resist and pattern are formed on the planar surface of insulator 130. In this regard, it is noted that the pattern, while not as wide as trench isolation (TI) trough 100″′, is open over trench isolation (TI) trough 100″′, as well as in two places over base and emitter 80. Moreover, the patterned opening over trench isolation (TI) trough 100″′ extends beyond the junction between substrate 20 and collector 30/subcollector 40, such that insulator 130 along the sidewall of trench isolation (TI) trough 100″′ is not as thick as the vertical portion of substrate 20 etched above. An insulator etch is performed such that a layer of insulation remains along one of the sidewalls of trench isolation (TI) trough 100″′, while the other side is etched along the vertical junction at collector 30/subcollector 40. Moreover, it is noted that the liner 110 is removed to the base and emitter 80. The photo resist is removed in an appropriate and conventional manner, e.g., stripping or etching, and the surface is cleaned.

A refractory metal film 140′ exhibiting adhesive/EM characteristics, e.g., TaN, TiN, etc., is applied over the device structure to cover the vertical, as well as horizontal surfaces, so that conductive layer 140′ is in contact with portions of base and emitter 80 and with bottom and insulated sides of trench isolation (TI) trough 100″′. Where the liner 140′ contacts a portion of the substrate 20, electrical isolation is provided by a schottky-barrier junction formed between the refractory metal film 140′ and the non-subcollector well 20. Alternatively, the non-subcollector well may comprise a portion of p-well 50, or any lightly doped region which may abut regions of the trench that are in physical contact with the refractory metal liner. A refractory metal 150, e.g., tungsten, is applied over the device structure by CA deposition. The upper surface of the device is smoothed, e.g., by CA polishing, to remove the refractory metal 150 and conductor 140 arranged vertically above insulator 130. At this point, typical back end of line (BEOL) processing can be performed, e.g., metal formation.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

While the invention has been described in terms of exemplary embodiments, those skilled in the art will recognize that the invention can be practiced with modifications and in the spirit and scope of the appended claims.

1. A device comprising:
a contact arranged within a trench extending from a top surface into a subcollector; and
a buried doped region formed along at least one of a bottom of the trench, which is formed, at least in part, in the subcollector, and at least one sidewall of the trench.

2. The structure in accordance with claim 1, wherein the contact is composed of a refractory metal.

3. The structure in accordance with claim 2, further comprising a refractory metal liner deposited between the contact and the buried doped region.

4. A method for an integrated circuit device, the method comprising:
forming a trench extending from a top surface into a subcollector;
forming a contact in the trench; and
forming a buried doped region formed along at least one of a bottom of the trench, which is formed at least in part in the subcollector, and at least one sidewall of the trench.

5. The process in accordance with claim 4, wherein the contact is composed of a refractory metal.

6. The process in accordance with claim 5, further comprising a refractory metal liner deposited between the contact and the buried doped region.

7. An integrated circuit comprising:
a trench extending into a subcollector;
a doped region along at least one of: at least one sidewall of the trench and a bottom of the trench; and
a refractory metal contained within the trench.

8. The integrated circuit in accordance with claim 7, further comprising a conductor coupled to the doped region and to the refractory metal.

9. The integrated circuit in accordance with claim 7, wherein at least a portion of the subcollector remains under the trench.

10. The integrated circuit in accordance with claim 7, further comprising a substrate on which the subcollector is formed, wherein the trench comprises a sidewall composed of the substrate.

11. The integrated circuit in accordance with claim 10, wherein the sidewall composed of the substrate is formed without removing any portion of the substrate.

12. The integrated circuit in accordance with claim 11, wherein a conductor is formed directly on each sidewall and a bottom of the trench, and the refractory metal is contained within the conductor.

13. The integrated circuit in accordance with claim 10, wherein the sidewall composed of the substrate is formed by removing at least a portion of the substrate.

14. The integrated circuit in accordance with claim 13, wherein the sidewall composed of the substrate is covered by an insulator, and the insulator does not extend beyond a vertical junction of the substrate and the subcollector.

15. The integrated circuit in accordance with claim 7, wherein the trench comprises a plurality of sidewalls, and each of the plurality of sidewalls contact the subcollector.

16. The integrated circuit in accordance with claim 15, wherein at least one sidewall of the trench is covered by an insulator, and the at least one sidewall is located on a sidewall nearest a vertical junction of the substrate and the subcollector.

17. The integrated circuit in accordance with claim 15, wherein each sidewall of the trench is covered by an insulator.

18. The integrated circuit in accordance with claim 7, further comprising a substrate on which the subcollector is formed, and a P-well adjacent the substrate, wherein the trench comprises a sidewall composed of the P-well.

19. The integrated circuit in accordance with claim 18, wherein the sidewall formed by the P-well junction is covered by an insulator, and the insulator extends beyond a vertical junction of the substrate and the subcollector.

20. The integrated circuit in accordance with claim 7, wherein the integrated circuit is a SiGe HBT transistor with a schottky diode metallurgical junction on side wall of the trench in contact with a collector.
